(19) United States
(12) Patent Application Publication
(10) Pub. No.: US 2001/0025228 A1
(43) Pub. Date: Sep. 27, 2001

(54) Method for evaluating measured data

(76) Inventors: Anton Prantl, Graz (AT); Jorg Schwemmlein, Graz (AT)

Correspondence Address: Pillsbury & Sutro LLP, Intellectual Property Group, Ninth Floor, 1100 New York Avenue, Washington, DC, 20005-3918, US

(21) Appl. No.: 09/813,134

(22) Filed: Mar. 21, 2001

(30) Foreign Application Priority Data
Mar. 21, 2000 (AT) GM212/2000

(51) Int. Cl. H03F 1/26

(52) U.S. Cl. 702/189

(57) ABSTRACT

There is disclosed a method for evaluating measured data, in which the measured data are digitalized and the digitalized measured data are disseminated to a processor, processed in the processor and the results are output. The digitalized measured data are intermediately stored in a shift register, in particular a FIFO memory, until completion of the acquisition of all measured data to be processed simultaneously, and read out together. After having read out all memory values necessary for processing, the computation of the results is executed in the processor. A device for obtaining measured values from measured data includes an A/D converter, a digital signal processor and a shift register arranged between the A/D converter and the digital signal processor.

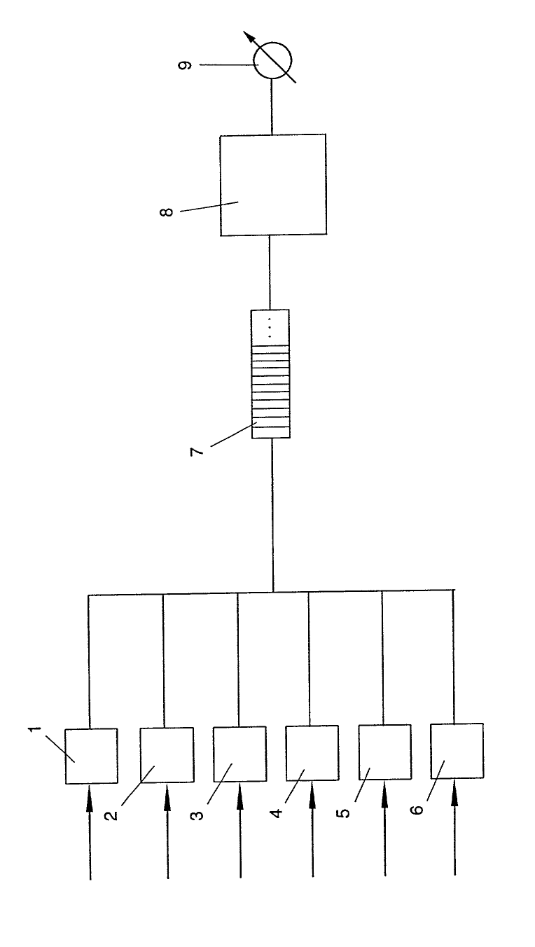

### BACKGROUND OF THE INVENTION

1. Field of the Invention

The invention relates to a method for evaluating measured data, in which the measured data are digitalized (ADC) and the digitalized measured data are disseminated to a processor (DSP), processed in said processor and the results are output, as well as a device for carrying out said method.

2. Prior Art

In electronic measuring devices in which different measuring signals are combined and electronically evaluated, such as, for instance, in measuring devices intended to measure the electrical power, it is, above all, a number of marginal conditions which determine the quality of such devices. It is, therefore, an essential goal in the realization of such measuring instruments to reduce the demands on power consumption. The power consumption of such devices to a high degree is a function of the clock rate of digital circuits, whereby a decrease of the clock rate could, at the same time, bring about a decrease of the noise created by such devices as well as a higher accuracy in respect to the analog components of such circuit arrangements.

By the example of a three-phase power indicator, it is clearly apparent that the clock rate cannot be readily lowered without basic changes in the circuit arrangement. In order to acquire measured data, such a device requires six analog-to-digital conversions (ADC) with the current and voltage data each having to be converted into digital signals for all three phases. These procedures have to be executed in a single sample period, whereby they are typically effected phase by phase such that three interrupts are necessary within a sample period. During the first two interrupts, the sampled measured data can only be stored, whereupon digital signal processing may be performed in a CPU or a digital signal processor (DSP). From that consideration results that a complete batch processing job is each required two times. At the third interrupt, computation may be started, based on all actual values. The required computation procedures are of low complexity, a number of small computation steps that differ from one another being required: In order to gain effective values, the measured voltage and current values must be squared, and in order to disseminate power measurements, the actual voltage values must be multiplied by the actual current values. The same holds for other types of computation, whereby all of these computation procedures necessitate a three-time execution, which implies a high overhead required for data storage and readout.

In computer-aided applications, various types of memories and intermediate memories are used, direct memory access controllers (DMA) being frequently employed. Such dynamic RAM controllers represent additional circuits as are required to operate dynamic RAMs. With a normal memory access, the address must be loaded into the RAM in two consecutive steps, whereby it is, furthermore, necessary in order to avoid data losses, to call all line addresses at least once within a predetermined period of time. If the contents of the memories are not read out cyclically, circuit accessories will become necessary in order to effect cyclic addressing between normal memory accesses. Such dynamic RAM controllers must be regularly subjected to refreshes, by which all line addresses are addressed once within a predetermined period of time, thus slightly reducing the availability of the memory. Various methods are known for partitioning a refresh in terms of time, the method of cycle stealing or the transparent or hidden refresh method being applied, in particular. In cycle stealing, the processor must come to rest for one cycle after predetermined periods of time such as, for instance, eight microseconds and execute a refresh step in order to enable the respective charge to be reapplied, since dynamic RAMs will loose their memory contents if the charge is not newly applied. In the main, relatively complex electronic components are required for such configurations.

Another configuration used in standard architectures comprises dual port memories. Such dual port memories are special RAMs that enable two independent processes to access common data. Thus, a data exchange is to be enabled between the two processes, to which end such a dual port memory must comprise two separate sets of address, data and control lines. Also this principle can, of course, not be realized without limitations, since it is principally not possible to write into the same memory location from either gate at one and the same time. With read-while-write memories, this problem is avoided in that one of the two gates serves to write only and the other gate serves to read only. In this case, two separate address decoders are necessary at all events so as to enable writing at one address and, at the same time, reading at the other address. In order to avoid access conflicts, also other relatively complex circuits have been proposed in this context, for instance, those referred to as priority decoders (arbiters), which will temporarily stop one of the two processes via a read signal, if overlapping memory accesses occur. In the main, all of those circuits call for a relatively high clock rate of the processor and complex and accordingly expensive memory components.

### SUMMARY OF THE INVENTION

The invention aims to provide a method of the initially defined kind as well as a device for carrying out said method, in which cost-effective memory components will do and by which the clock rate and hence the power consumption of the device will be reduced, at the same time. To this end, the method according to the invention is essentially characterized in that the digitalized measured data are intermediately stored in a shift register, in particular a FIFO memory, until completion of the acquisition of all measured data to be processed simultaneously, and read out together, whereupon, after having read out all memory values necessary for processing, the computation of the results is executed in the processor. By using a shift register as a memory, the sample values will be obtained together, only one interrupt being generated as the shift register is complete. After this, a block transfer of all memory contents contained in the shift register into the memory of a computer (DSP memory) is effected, whereby the number of computation steps is drastically reduced. Block processing also enables additional functions such as, for instance, the consideration of filter coefficients to be taken into account by a single input only.

In principle, RAMs may be operated as shift registers if the addresses are cyclically counted through. Thus, at each address, the stored data are read out first, and subsequently the new data are read in. In principle, different configurations of such shift registers are known, first-in first-out memories (FIFO memories) having proved to be particularly advantageous. With a FIFO memory, the data at the output appear in the same order as they were input. The word read in first also is read out first. With a FIFO memory, this procedure may proceed completely asynchronously as opposed to ordinary shift registers and the readout pulse is, therefore, independent of the readin pulse. In a particularly preferred manner, FIFOs may, therefore, be used to couple asynchronous systems. The function resembles that of a queue. The data migrate from the input to the output no longer at a fixed pulse, but wait in the register only until all preceding data have been output. During the input, the data are forwarded to the lowest free memory location and from there are shifted to the output at the readout pulse. The runtime in that case may be substantially reduced by special configurations such as, for instance, by designing the FIFO memory as a ring memory. Bearing in mind the considerably reduced number of computation steps that are required for a complete evaluation, the clock rate of the processor can be substantially lowered, thus considerably reducing power consumption and noise.

The device according to the invention for obtaining measured values from measured data, which includes at least one A/D converter and a digital signal processor, is essentially characterized in that a shift register is arranged between ADC and DSP, the configuration advantageously being devised such that the shift register is designed as a FIFO memory.

By using such a FIFO memory, the number of interrupts, at first, is significantly reduced, which results in substantially less computation work for typical computation procedures such as block processing. The computer, thus, is able to operate at a substantially lower clock rate, the respective expenditure involved in the intermediate storage of intermediate results likewise being substantially reduced. In a typical application, a FIFO memory may collect ten sample values of all six ADC measurements as in the case of a power indicator. As soon as the FIFO memory has been filled, an interrupt is generated, which triggers the block transfer of sixty memory contents into the DSP memory, from which it is already clearly apparent that the computation work involved in batch processing is reduced to a sixtieth.

### BRIEF DESCRIPTION OF THE DRAWING

The drawing schematically illustrates a device for obtaining measured values from six analog measured data each.

### DETAILED DESCRIPTION OF A PREFERRED EMBODIMENT

Analog-to-digital converters (ADCs) represented at 1, 2, 3, 4, 5 and 6 have analog signals available as inputs. In these ADCs, the signals are converted into digital values and filed in a FIFO shift register 7. A computer 8, i.e., the CPU with the pertinent memory, executes the computations aimed for digital signal processing. The computer, therefore, also may be referred to as a DSP. The results of such computations may be indicated by means of a measuring instrument, the display being feasible immediately as a digital display. Yet, it is also feasible to directly use the computational result in the digital form for further control or regulation purposes.

What we claim is:

1. In a method for evaluating measured data by digitalizing said measured data in an analog-to-digital converter so as to obtain digitalized measured data and disseminating said digitalized measured data to a digital signal processor for processing said digitalized measured data by computation and outputting respective measured values, the improvement comprising
providing a shift register between said analog-to-digital converter and said digital signal processor,
intermediately storing said digitalized measured data in said shift register until completion of the acquisition of all measured data to be processed simultaneously,
reading out together all measured data to be processed simultaneously, and
executing processing of said digitalized measured data by computation in said digital signal processor for obtaining respective measured values.

2. In a device to be used for obtaining measured values by evaluating measured data and of the type including at least one analog-to-digital converter configured to digitalize said measured data and a digital signal processor configured to process said measured data upon digitalization by computing respective measured values, the improvement comprising a shift register arranged between said at least one analog-to-digital converter and said digital signal processor and configured to intermediately store said measured data upon digitalization until completion of the acquisition of all measured data to be processed simultaneously.

3. A device as set forth in claim 2, wherein said shift register is designed as a FIFO memory.

4. A method as set forth in claim 1, wherein said shift register is designed as a FIFO memory.
